(19) United States
(12) Patent Application Publication
(10) Pub. No.: US 2026/0352227 A1
(43) Pub. Date: Nov. 5, 2026

(54) VARIABLE BIT LENGTH COMPRESSION OF MATRICES

(71) Applicant: Microsoft Technology Licensing, LLC, Redmond, WA (US)

(72) Inventors: Li ZHANG, Saratoga, CA (US); Sivakanth GOPI, Santa Clara, CA (US)

(21) Appl. No.: 19/195,318

(22) Filed: Apr. 30, 2025

(51) Int. Cl. H03M 7/30; H03M 7/40

(52) U.S. Cl. CPC H03M 7/3082; H03M 7/3066; H03M 7/4031; H03M 7/6011

(57) ABSTRACT

Methods, apparatuses, and products for variable bit length compression of matrices, including: identifying, from a dataset comprising a plurality of values, one or more outliers based on a distribution of the dataset; applying a fixed-length quantizer to the one or more outliers to generate one or more quantized outliers; and applying a length-limited encoder to the one or more quantized outliers and a remainder of the plurality of values to generate a compressed dataset comprising a plurality of encoded values.

### BACKGROUND

Matrix operations are used in many areas of computing including in the training or use of machine learning models. For example, matrices weights of a machine learning model can be encoded as a matrix. Training the machine learning model or performing inference operations using the machine learning model may require multiplying or performing a linear transformation using the matrix of weights. As machine learning models grow in size and complexity the size and the computational complexity of performing operations using these matrices also increases.

To address this increase in complexity, some computing systems executing these machine learning models may use dedicated hardware computational units to perform these matrix operations. These computational units may include graphics processing units (GPUs), artificial intelligence (AI) accelerators, or other hardware accelerators. Though these computational units allow for faster computation of matrix operations, the matrices used in these operations must still be transferred to the computational units prior to execution. The amount of time required to transfer a matrix to a computational unit is based on the size of the matrix, potentially making the memory bandwidth to the computational unit a bottleneck in using or training the machine learning model.

Matrices can be compressed to reduce the amount of time required to transfer a matrix to a computational unit for processing. Fixed-rate encoders can be used to encode each value of a matrix as an encoded value of a fixed size. Though fixed-length encoders may allow for efficient decoding using lookup tables the provided compression rate may be less than other compression approaches. Variable-length encoders can be used to encode each value of a matrix as an encoded value of variable size. Though this may provide for a better compression rate than fixed-length encoders, the computational complexity for decoding is also increased due to the variable size of the encoded values.

### SUMMARY

According to embodiments of the present disclosure, various methods, apparatus, and products for variable bit length compression of matrices are described herein. In some aspects, variable bit length compression of matrices includes: identifying, from a dataset comprising a plurality of values, one or more outliers based on a distribution of the dataset; applying a fixed-length quantizer to the one or more outliers to generate one or more quantized outliers; and applying a length-limited encoder to the one or more quantized outliers and a remainder of the plurality of values to generate a compressed dataset comprising a plurality of encoded values. In some aspects, an apparatus may include a memory and one or more processing devices, operatively coupled to the memory, the one or more processing devices configured to perform similar steps. In some aspects, a computer program product comprising a computer readable storage medium may store computer program instructions that, when executed, perform similar steps.

### BRIEF DESCRIPTION OF DRAWINGS

FIG. 1 sets forth a diagram of an example computing system 100 for variable bit length compression of matrices in accordance with some embodiments of the present disclosure.

FIG. 2A sets forth an example table mapping encoded values to quantized values for variable bit length compression of matrices in accordance with some embodiments.

FIG. 2B sets forth an example data structure for decoding compressed matrices for variable bit length compression of matrices in accordance with some embodiments.

FIG. 3 sets forth a flow chart illustrating an example method of variable bit length compression of matrices in accordance with some embodiments.

FIG. 4 sets forth a flow chart illustrating an additional example method of variable bit length compression of matrices in accordance with some embodiments.

FIG. 5 sets forth a flow chart illustrating an additional example method of variable bit length compression of matrices in accordance with some embodiments.

FIG. 6 sets forth a flow chart illustrating an additional example method of variable bit length compression of matrices in accordance with some embodiments.

FIG. 7 sets forth a flow chart illustrating an additional example method of variable bit length compression of matrices in accordance with some embodiments.

FIG. 8 sets forth a flow chart illustrating an additional example method of variable bit length compression of matrices in accordance with some embodiments.

FIG. 9 sets forth a flow chart illustrating an additional example method of variable bit length compression of matrices in accordance with some embodiments.

FIG. 10 illustrates an exemplary computing device that may be specifically configured to perform one or more of the processes described in the present disclosure.

FIG. 11 sets forth a block diagram of a cloud service provider service architecture in accordance with some embodiments of the present disclosure.

### DESCRIPTION OF EMBODIMENTS

Matrix operations are used in many areas of computing including in the training or use of machine learning models. For example, generative artificial intelligence (AI) models such as large language models (LLMs) require mathematical operations to be performed on matrices with large numbers of values. This often includes transferring the matrix from memory to a computational unit such as a graphics processing unit (GPU) or AI accelerator that performs these matrix operations. Memory bandwidth limits to these computational units may form a bottleneck in transferring matrices, reducing the overall performance and efficiency of the functions dependent on these matrix operations.

Matrices can be compressed to account for these bandwidth limits and improve performance. For example, fixed-rate or fixed-length encoders map each value to an encoded value with a fixed number of bits. A lookup table can be used to decode a compressed matrix by mapping a set of bits into the encoded value. This provides for high decoding efficiency but may introduce some amount of distortion. As another example, variable rate encoders may map each value to a variable number of bits. This may provide for a better compression rate than a fixed-rate encoder but, as values are mapped to a variable number of bits, this may make decoding less efficient is it requires additional computation to identify the bounds of the bits of a particular value to be decoded.

To address these shortcomings, the approaches set forth herein compress values of a matrix using a two-phase encoding approach that includes a combination of fixed-length encoding and length-limited, variable rate encoding. First, outliers of a matrix (i.e., matrix values that deviate significantly from the other matrix values) are dynamically identified and quantized by clustering the outliers and mapping them to their centroid cluster center. The remaining values of the matrix are quantized using some other approach such as uniform quantization. The quantized outliers and the quantized remaining values are then encoded using a length-limited encoder such as a length-limited Huffman encoder. By first quantizing the outliers through clustering, the overall distribution of the quantized remaining values and the quantized outliers is denser. This provides for a better compression-to-distortion ratio than only using a length-limited encoder on the values of the matrix. The compressed matrix can be decompressed using a lookup table, allowing for efficient decoding in hardware.

Due to the prevalence of matrix operations in various areas of computing, efficient performance of these matrix operations is essential to overall system performance. Though matrix compression allows for faster data transfer to computational units performing these matrix operations, the level of distortion introduced by compression must not significantly impact the accuracy of the resulting calculations. The approaches set forth herein provide for matrix compression with a greater compression-to-distortion ratio than existing solutions, while still enabling efficient hard-ware-accelerated decompression, for instance, using lookup tables.

The described approaches effectively reduce memory bandwidth demands by significantly compressing matrices used in AI computations, while enabling rapid hardware-based decompression. This reduction in data transfer directly improves computational speed, minimizes distortion, and enhances computational accuracy. Consequently, one or more of the embodiments disclosed herein lower computational costs and facilitate scalable and efficient deployment of large AI models. This results in improved performance and adoption, increasing overall revenue.

Implementing the described compression techniques can result in reduced hardware resource requirements and associated operational expenses by alleviating memory bandwidth constraints. This results in faster processing and lower latency for AI-driven products and services, enhancing overall system responsiveness and user satisfaction. Additionally, by enabling efficient execution of larger and more complex AI models, the quality and accuracy of AI offerings can be improved, strengthening competitive positioning and market differentiation. Together, these advantages support higher adoption rates, increased customer retention, and greater overall revenue growth.

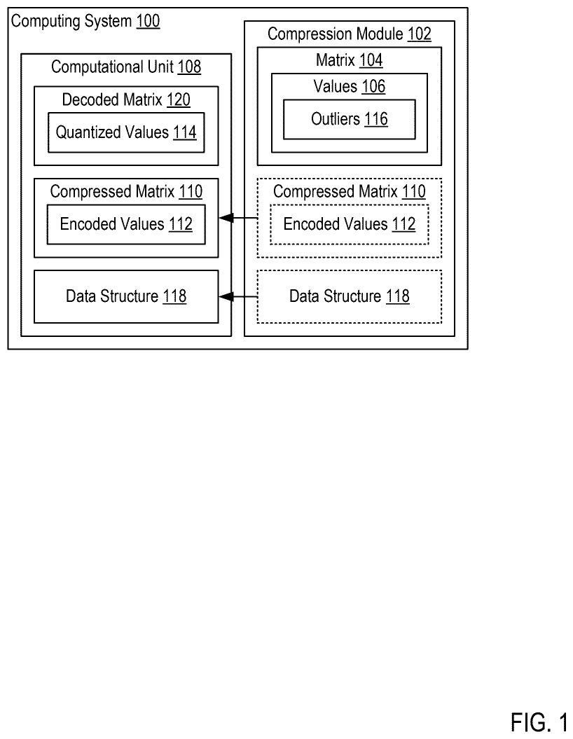

To begin, FIG. 1 sets forth a diagram of an example computing system 100 for variable bit length compression of matrices in accordance with some embodiments of the present disclosure. The computing system 100 includes one or more computing devices and may include a variety of computing system 100 configurations. For example, the computing system 100 may include a cloud-based computing system 100, an on-premises computing system 100, combinations thereof, or other computing systems 100 as can be appreciated. The computing system 100 includes a compression module 102. The compression module 102 is a combination of hardware and/or software that applies compression as described below to a dataset so as to reduce the amount of data encoding the dataset. In the example computing system 100 of FIG. 1, a dataset to be compressed by the compression module 102 includes a matrix 104. A matrix 104 is a multidimensional data structure storing multiple numerical values 106. For example, a matrix 104 having M rows and N columns will include M*N values 106. Although the following examples are described in the context of a matrix 104, readers will appreciate that the approaches set forth herein may be applied to any dataset that includes multiple values 106. In some embodiments, these datasets may include any number of dimensions.

In some embodiments, the matrix 104 is associated with some operation of a machine learning model, such as a training operation or an inference operation. Readers will appreciate that performing these operations requires performing mathematical operations applied to matrices 104, hereinafter referred to as “matrix operations,” such as matrix multiplication, linear transformations, or other mathematical functions or operations that use a matrix 104 as a parameter or operand. For example, feed-forward neural networks may use linear transformations to perform inference operations. As another example, backpropagation during training of a machine learning model may use matrix multiplication. Accordingly, in some embodiments, the matrix 104 may include any matrix 104 used as a datapoint in some mathematical operation performed during training and/or use of a machine learning model. For example, in some embodiments, the matrix 104 may include one or more weights of a trained model or of a model being trained. As another example, in some embodiments, the matrix 104 may include one or more values 106 generated as a function of an input to the machine learning model. As a further example, the matrix 104 may include an intermediary datapoint generated as part of a training and/or inference operation.

The computing system 100 also includes a computational unit 108. The computational unit 108 is a hardware component, such as a peripheral hardware component, with dedicated processing capabilities (e.g., with dedicated processors, memory, or other resources as can be appreciated. For example, in some embodiments, the computational unit 108 may include a hardware accelerator such as a graphics processing unit (GPU), an artificial intelligence (AI) accelerator, or another hardware accelerator as can be appreciated. In some embodiments, the computational unit 108 is used to perform some mathematical operation using a dataset such as a matrix 104. For example, the computational unit 108 is used to perform matrix operations as described above.

In order to perform a matrix operation on the matrix 104, the matrix 104 must be provided to the computational unit 108 for processing. For example, in some embodiments, the matrix 104 is loaded from memory of the computing system 100 and provided to the computational unit 108 using a bus or interface. As matrices 104 grow in size (e.g., as the number of included values 106 increases) the amount of time required to transfer a matrix 104 will also increase. For sufficiently large matrices 104 a memory bandwidth limit (e.g., due to memory transfer limits of a bus or interface) may become a bottleneck in transferring a matrix 104 to a computational unit 108. This increased transfer time increases the overall amount of time to perform the function using the matrix 104 (e.g., the training or inference operation of a machine learning model), negatively impacting overall performance.

Accordingly, the compression module 102 is used to generate a compressed matrix 110 that is smaller (e.g., requires fewer bits to encode) than the original matrix 104. The compressed matrix 110 may then be provided to the computational unit 108 (e.g., via a bus or interface coupling the computational unit 108) for decoding and use in the matrix operations. As the compressed matrix 110 is smaller than the original matrix 104 the amount of time required to transfer the compressed matrix 110 to the computational unit 108 is reduced, improving performance. The compressed matrix 110 has a similar dimensionality to the original matrix 104 and stores encoded values 112. Each encoded value 112 is a compressed or encoded version of a corresponding value 106 from the original matrix 104. Thus, the compressed matrix 110 is smaller than the original matrix 104 by virtue of the encoded values 112 requiring fewer bits than their corresponding value 106.

After compressing a value 106 into an encoded value 112, the original value 106, or an approximation thereof, is generated from the encoded value 112 by decoding the encoded value 112. An encoded value 112 compressed using lossless compression is decoded into the original value 106. In other words, the original value 106 and the decoded value will be identical. For lossy compression there is some difference between the original value 106 and the decoded value. For example, where a value 106 is quantized prior to encoding, the decoded value will be the quantized value rather than the original value 106. The difference between the original value 106 and the decoded value is hereinafter referred to as “distortion.” When compressing a value 106 into an encoded value 112 the number of bits used to encode the encoded value 112 is referred to as a “rate.” Accordingly, an approach for compressing values 106 may be characterized by a tradeoff between the rate and the distortion. For example, a compression approach should have a low rate so as to use the least data possible while maintaining an acceptably low distortion to maintain data integrity and performance.

In some existing approaches, a fixed-length encoder is used to compress a value 106 into an encoded value 112 having a predefined or fixed number of bits. As the number of bits used for each encoded value 112 is fixed these fixed-length encoders may also be referred to as fixed-rate encoders interchangeably. To do so, in some embodiments, each value 106 is quantized so as to be mapped to some quantized value 114. The quantized value 114 may then be encoded as an encoded value 112 using the fixed number of bits. In some embodiments, a lookup table is generated during the compression process that maps each encoded value 112 to the corresponding quantized value 114. This lookup table may then be used to decode the encoded values 112 by identifying the mapped quantized value 114. As decoding the encoded values 112 only requires use of a lookup table as opposed to more complex calculations the decoding process is comparatively computationally simple, resulting in fast decoding performance. However, the use of a fixed number of bits for each encoded value 112 does not provide as low a compression rate as other encoding approaches, such as with a variable-length encoder.

Using a variable-length or variable-rate encoder a value 106 is compressed into an encoded value 112 with a variable number of bits. For example, a Huffman encoder encodes values 106 of a dataset into “codes” (e.g., encoded values 112) with varying numbers of bits based on the frequency of occurrence of the values 106 in the dataset. More frequent values 106 are represented by fewer bits while less frequent values 106 are represented by more bits. In some embodiments, these values 106 are quantized prior to encoding. These codes or encoded values 112 may include prefix-free codes whereby the bit string of some code or encoded value 112 is never the prefix of the bit string of any other code or encoded value 112. As variable-length encoders may have unbound lengths for the encoded values 112 the decoding process is more computationally expensive than other approaches, such as those using a lookup table. Some variable-length encoders may include length-limited encoders where an encoded value 112 may have some maximum number of bits. Though this may mitigate the computational complexity of decoding the resulting quantizers introduce unacceptable levels of distortion.

To address these concerns, the compression module 102 uses a combination of fixed-length quantization and variable-length encoding to compress a matrix 104 into a compressed matrix 110. To begin, the compression module 102 identifies one or more outliers 116. An outlier 116 is a value 106 that significantly differs from other values 106 in the dataset (e.g., in the matrix 104). Outliers 116 may be identified according to any approach as would be appreciated by one skilled in the art. For example, in some embodiments, a value 106 is identified as an outlier 116 where its absolute value exceeds some threshold t. In some embodiments, this threshold t may include a tunable or configurable hyperparameter defined based on various design or engineering considerations. As another example, in some embodiments, identifying the one or more outliers 116 includes identifying some number of outliers with the highest absolute values. Continuing with this example, assuming a configurable parameter q of ten percent, identifying the one or more outliers 116 includes identifying, as outliers 116, the top q values 106 (e.g., the top ten percent) ranked by their absolute values. In this example, it is assumed that the distribution is symmetric around zero. As yet another example, in some embodiments where the distribution is not symmetric around zero, identifying the one or more outliers 116 includes identifying, at the outliers 116, the q/2 values 106 with the lowest absolute value and the q/2 values 106 with the highest absolute value. As a further example, in some embodiments, a value 106 is identified as an outlier 116 where the value 106 exceeds some factor (e.g., 1.5 times) the interquartile range (IQR) above the third quartile or below the first quartile. Other approaches may also be used to identify these outliers 116.

Next, the compression module 102 quantizes each outlier 116 using a fixed-length quantizer. Quantization maps a set of values 106 such as continuous values to a smaller set of discrete quantized values 114. A fixed-length quantizer maps values 106 (e.g., the identified outliers 116) to quantized values 114 encoded using a fixed number of bits. Quantizing the outliers 116 may be performed according to any approach as would be appreciated by one skilled in the art for quantizing numbers. For example, in some embodiments, the outliers 116 are clustered by applying a clustering algorithm to the outliers 116. In some embodiments, this may include applying k-means clustering to create k clusters of outliers 116. In some embodiments, k may also include a tunable or configurable hyperparameter defined based on various design or engineering considerations. In some embodiments, each outlier 116 is quantized by mapping each outlier 116 to the centroid of its corresponding cluster.

After quantizing the outliers 116 the compression module 102 quantizes a remainder of the values 106 other than the outliers 116. In some embodiments, the compression module 102 quantizes the remainder of values 106 using uniform quantization. When performing uniform quantization each value 106 is mapped to a quantized value 114 from a uniform distribution of possible quantized values 114. For example, in some embodiments, a set of possible quantized values 114 is generated for each interval of a fixed size h. In some embodiments, h is a configurable hyperparameter. Accordingly, each value 106 is quantized by rounding each value 106 to the closest multiple of the size h.

The compression module 102 then applies a length-limited encoder to the quantized values 114 (e.g., the outliers 116 quantized using a fixed-length quantizer and the remainder of values 106 quantized using uniform quantization) to generate, for each quantized value 114, a corresponding encoded value 112. The length-limited encoder is a type of variable length encoder. As is set forth above, a variable length encoder such as a Huffman encoder encodes values 106 as encoded values 112 using a variable number of bits. The length-limited encoder generates encoded values 112 with a variable number of bits up to some maximum number of bits. In some embodiments, this maximum number of bits may correspond to a number of bits used by the fixed-length quantizer to quantize the outliers 116. In some embodiments, the maximum number of bits may include a configurable hyperparameter. In some embodiments, rather than use a length-limited encoder, the compression module 102 may encode the quantized values 114 into encoded values 112 using a non-length-limited variable length encoder. The result of applying the length-limited encoder to the quantized values 114 is a compressed matrix 110 including set of encoded values 112 each corresponding to a value 106 from which it was generated and having a variable number of bits. In some embodiments, the compressed matrix 110 may be encoded as a bit string. For example, the bits for each encoded value 112 may be concatenated together to form the bit string.

Quantizing the outliers 116 and the remainder of values 106 as described above produces a set of quantized values 114 having at most 2t/h+k distinct values 106. This reduces variance in the set of quantized values 114 to be encoded using the length-limited encoder. Readers will appreciate that, as the number of bits used to encode an encoded value 112 by a length-limited encoder is based on the probability or frequency of the corresponding value 106 in the dataset to be encoded, the variance of the dataset will affect the overall compression rate achieved. Thus, quantizing the outliers 116 differently than the remainder of values 106 (e.g., using fixed-length cluster-based quantization) provides a significant reduction in variance of the quantized values 114 compared to approaches whereby all values 106 are quantized using the same approach, thereby improving the compression rate of the length-limited encoder.

As is set forth above, in some embodiments, the compressed matrix 110 may be encoded as a bit string. In order to enable decoding of the compressed matrix 110 and the included encoded values 112 the compression module 102 generates a data structure 118 that maps possible substrings of the bit string to a corresponding quantized value 114. In some embodiments, this data structure 118 includes a lookup table or another data structure as can be appreciated. In some embodiments, this data structure 118 includes a number of entries based on a maximum number of bits used by the length-limited encoder. In some embodiments, the data structure 118 includes an entry for each possible bit substring having the maximum number of bits used by the length-limited encoder. For example, where the length-limited encoder uses a maximum of eight bits, the data structure 118 will include two hundred and fifty-six entries.

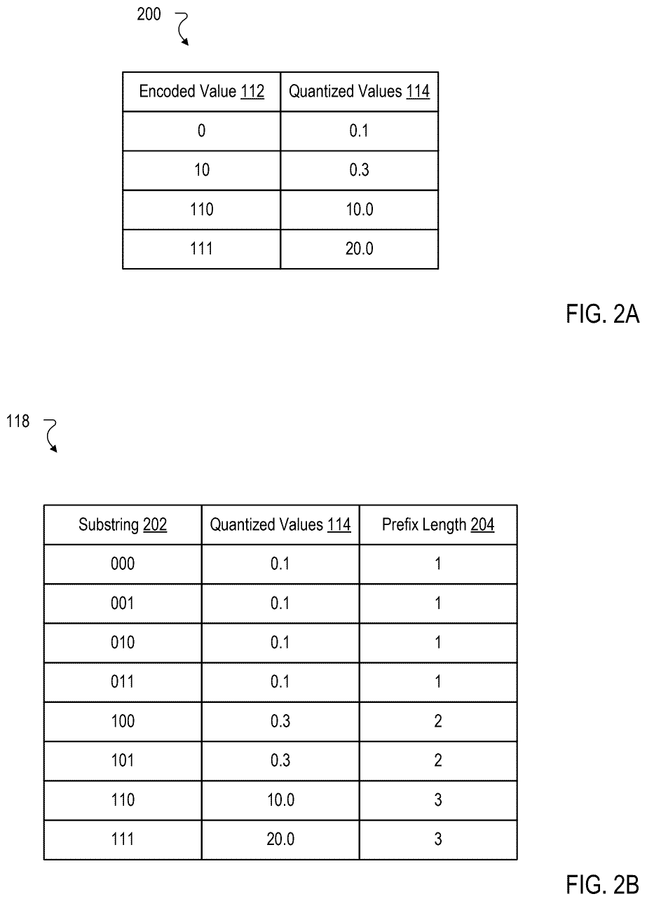

As an illustrative example, FIG. 2A shows an example table 200 mapping encoded values 112 to quantized values 114. In this example, assume that a length-limited encoder having a maximum length of three bits was used to encode a set of quantized values 114 generated from a matrix 104 of values 106. As shown, quantizing these values 106 as described above produces a set of four distinct quantized values 114 in the table 200. Each of the quantized values 114 is encoded using the length-limited encoder as an encoded value 112 of different bit lengths. For example, assuming that the quantized values 114 were encoded using a Huffman encoder, the quantized value 114 of 0.1 occurs most frequently in the set of quantized values 114. Accordingly, this quantized value 114 is encoded using the fewest bits. Conversely, the quantized values 114 of 10.0 and 20.0 occur the least frequently in the set of quantized values 114 and are encoded using the most bits. Particularly, these encoded values 112 are prefix codes or prefix-free codes in that each encoded value 112 is not a prefix of any other encoded value 112 in the table 200. In other words, a prefix code or prefix-free code is an encoded value 112 that does not match the leading bits of any other encoded value 112.

These encoded values 112 and quantized values 114 may then be used to generate the example data structure 118 shown in FIG. 2B. The example data structure 118 includes eight entries, one for each possible three-bit substring 202 of a bit string encoding the compressed matrix 110. Each entry also includes a quantized value 114 encoded by a prefix of the substring 202 (e.g., by one or more leading bits of the substring 202). Particularly, the quantized value 114 encoded by an encoded value 112 matching a prefix of the substring 202. For example, the substrings 202 of “000,” “001,” “010,” and “001” each include a prefix of “0.” This prefix “0” matches the encoded value 112 for the quantized value 114“0.1” as shown in the table 200 of FIG. 2A. Accordingly, each of these entries includes a quantized value 114 of “0.1.”

Each entry also includes a prefix length 204 indicating a number of bits used for the corresponding prefix (e.g., for the corresponding encoded value 112). Returning to the example above, the substrings 202 of “000,” “001,” “010,” and “001” each include a prefix of “0,” which has a prefix length 204 of one. As another example, the substrings 202 “110” and “111” each match encoded values 112 using three bits. Accordingly, the prefix length 204 for these entries is three. The prefix length 204 will be used to decode a bit string encoding a compressed matrix 110, to be described in further detail below.

Turning back to FIG. 1, after the compression module 102 has generated the compressed matrix 110 and the data structure 118 they are provided to the computational unit 108. The computational unit 108 must decode the compressed matrix 110 into a decoded matrix 120 of the quantized values 114 before performing any matrix operations using the decoded matrix 120. To do so, in some embodiments, the computational unit 108 selects a leading substring 202 of the bit string encoding the compressed matrix 110. This selected substring 202 will have a number of bits equal to the maximum number of bits used by the length-limited encoder. In other words, this selected substring 202 will have the same number of bits as the substrings 202 in the entries of the data structure 118.

Next, the computational unit 108 identifies an entry in the data structure 118 whose substring 202 matches the selected substring 202. The quantized value 114 for that entry is then added to a set of quantized values 114 of the decoded matrix 120. An index for the selected substring 202 is then shifted by a number of bits equal to the prefix length 204 of the entry. In some embodiments, this may include incrementing a pointer or identifier for the first bit of the selected substring 202 by this number of bits. In some embodiments, this may include performing a bit shift operation (e.g., a shift left) on the bit string encoding the compressed matrix 110 by this number of bits. This serves to update the selected substring 202 for the decoding process. The process of selecting a fixed-length substring 202, identifying a matching data structure 118 entry, adding the quantized value 114 of the entry to the decoded matrix 120, and shifting the index of the selected substring 202 by the prefix length 204 is repeatedly performed until the end of the compressed matrix 110 bit string has been reached, thereby ending the decoding process and completing the decoded matrix 120. Readers will appreciate that, as this decoding process is largely dependent on a lookup table data structure 118 and index shifting, decoding the compressed matrix 110 is computationally inexpensive and may be implemented and/or accelerated using hardware components.

The computational unit 108 may then perform one or more matrix operations using the decoded matrix 120. As the compressed matrix 110 uses fewer bits than the original matrix 104 the amount of time required to transfer the compressed matrix 110 to the computational unit 108 is reduced. This reduces the amount of time to perform the associated tasks that require matrix operations, such as inference or training operations, thereby improving performance. Particularly, the approaches set forth above provide for a high rate of compression with low distortion and computationally inexpensive decoding, further improving overall performance.

Consider an example where a computing system 100 executes a large language model (LLM) for processing some inputs such as user prompts. Computing systems 100 supporting LLMs or other large of complex machine learning models often use computational units 108 such as GPUs or AI accelerators to accelerate processing of model inputs by leveraging their ability to perform mathematical operations, such as matrix operations, more quickly and efficiently. Accordingly, to process an input to the LLM, the compression module 102 compresses a matrix 104 of model weights (e.g., as values 106) as described above. The compressed matrix 110 of model weights is provided to the computational unit 108 and decoded into a decoded matrix 120 of quantized model weights (e.g., as quantized values 114). The computational unit 108 may then perform matrix operations to support processing an input to the LLM, such as a linear transformation or matrix multiplication operation, using the decoded matrix 120. As the matrix 104 was compressed using the approaches set forth above, transferring the compressed matrix 110 requires less time than an uncompressed matrix 104 or using approaches with lower compression rates. Moreover, as the compressed matrix 110 can be decoded efficiently using a data structure 118 lookup table, the amount of time and processing resources required to decode the compressed matrix 110 is reduced, reducing the processing time for the input to the LLM. Thus, overall processing time for the input to the LLM is reduced while maintaining an acceptable level of distortion so as to prevent performance degradation and maintain accuracy of the LLM.

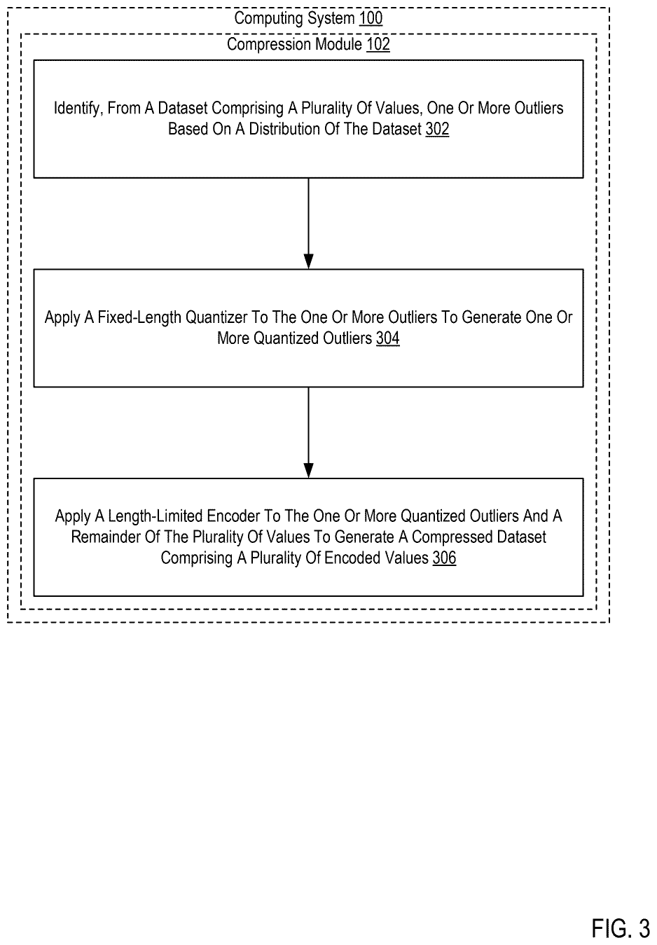

For further explanation, FIG. 3 sets forth a flowchart of an example method of variable bit length compression of matrices in accordance with some embodiments of the present disclosure. The method of FIG. 3 may be performed, for example, by a compression module 102 of a computing system 100 of FIG. 1. The method of FIG. 3 includes identifying 302, from a dataset comprising a plurality of values 106, one or more outliers 116 based on a distribution of the dataset. The dataset may include any set of multiple numerical values 106 as can be appreciated. For example, in some embodiments, the dataset includes a matrix 104 or another multidimensional data structure as can be appreciated.

An outlier 116 is a value 106 that significantly differs from other values 106 in the dataset. Outliers 116 may be identified according to any approach as would be appreciated by one skilled in the art. For example, in some embodiments, a value 106 is identified as an outlier 116 where its absolute value exceeds some threshold t. In some embodiments, this threshold t may include a tunable or configurable hyperparameter defined based on various design or engineering considerations. As another example, in some embodiments, identifying the one or more outliers 116 includes identifying some number of outliers with the highest absolute values. Continuing with this example, assuming a configurable parameter q of ten percent, identifying the one or more outliers 116 includes identifying, as outliers 116, the top q values 106 (e.g., the top ten percent) ranked by their absolute values. In this example, it is assumed that the distribution is symmetric around zero. As yet another example, in some embodiments where the distribution is not symmetric around zero, identifying the one or more outliers 116 includes identifying, at the outliers 116, the q/2 values 106 with the lowest absolute value and the q/2 values 106 with the highest absolute value. As a further example, in some embodiments, a value 106 is identified as an outlier 116 where the value 106 exceeds some factor (e.g., 1.5 times) the interquartile range (IQR) above the third quartile or below the first quartile. Other approaches may also be used to identify these outliers 116.

The method of FIG. 3 also includes applying 304 a fixed-length quantizer to the one or more outliers 116 to generate one or more quantized outliers 116. A fixed-length quantizer maps the one or more outliers 116 to a set of quantized values 114 encoded using a fixed number of bits. In other words, each outlier 116 is mapped or converted to a quantized value 114, resulting in a set of quantized values 114 each corresponding to some outlier 116 from which it was generated. Quantizing the outliers 116 may be performed according to any approach as would be appreciated by one skilled in the art for quantizing numerical values 106. For example, in some embodiments, as will be described in further detail below, applying 304 the fixed-length quantizer includes applying a clustering algorithm to the one or more quantized outliers 116. In some embodiments, quantization approaches may also be applied 304 to the one or more outliers 116.

The method of FIG. 3 also includes applying 306 a length-limited encoder to the one or more quantized outliers 116 and a remainder of the plurality of values 106 other than the one or more outliers 116 to generate a compressed dataset comprising a plurality of encoded values 112. For example, where the dataset of values 106 includes a matrix 104 the compressed dataset may include a compressed matrix 110. The length-limited encoder is a type of variable length encoder that generates encoded values 112 with a variable number of bits up to some maximum number of bits. For example, in some embodiments, the length-limited encoder includes a length-limited Huffman encoder. Accordingly, in some embodiments, each encoded value 112 may include a Huffman code. In some embodiments, each encoded value 112 may include a prefix code or prefix-free code such that the bits encoding each encoded value 112 is not a prefix of any other encoded value 112. In some embodiments, this maximum number of bits may correspond to a number of bits used by the fixed-length quantizer to quantize the outliers 116. In some embodiments, the compressed dataset (e.g., the compressed matrix 110) may be encoded as a bit string. For example, the bits for each encoded value 112 may be concatenated together to form the bit string. In some embodiments, the compressed dataset may be encoded using other approaches or formats.

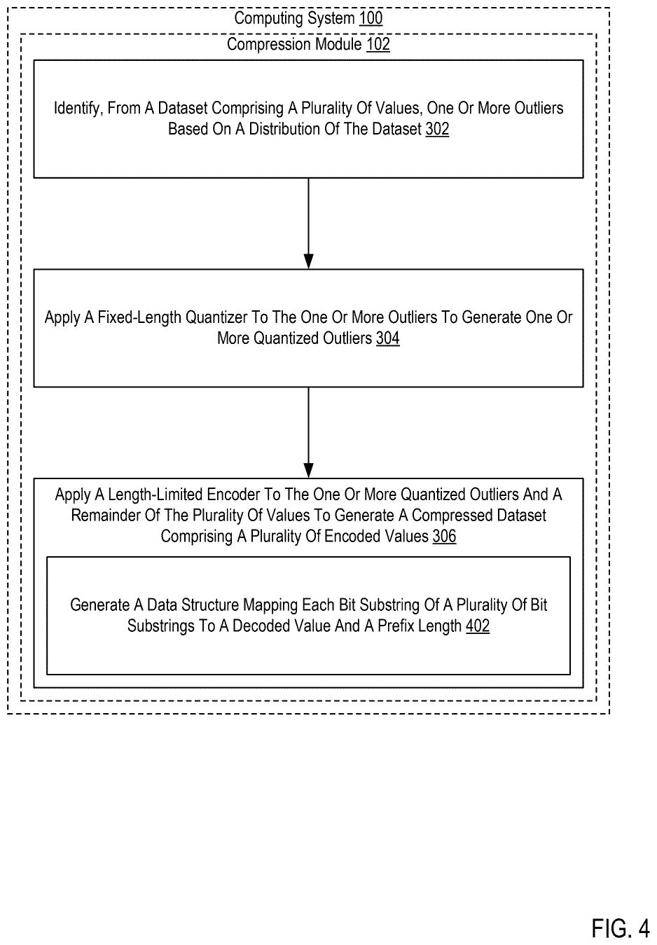

For further explanation, FIG. 4 sets forth a flowchart of another example method of variable bit length compression of matrices in accordance with some embodiments of the present disclosure. The method of FIG. 4 is similar to FIG. 3, differing in that applying 306 a length-limited encoder to the one or more quantized outliers 116 and a remainder of the plurality of values 106 other than the one or more outliers 116 to generate a compressed dataset comprising a plurality of encoded values 112 also includes generating 402 a data structure 118 mapping each bit substring 202 of a plurality of bit substrings 202 to a decoded value and a prefix length 204. In some embodiments, this data structure 118 is used by the computational unit 108 to decode encoded values 112 of a compressed dataset.

Assume that the compressed dataset (e.g., a compressed matrix 110) of encoded values 112 is encoded as a bit string. In some embodiments, the data structure 118 maps each possible substring 202 of a particular bit length to a decoded value 114 and a prefix length 204. For example, in some embodiments, the data structure 118 includes entries for each possible substring 202 having a number of bits equal to the maximum number of bits that may be used by the length-limited encoder to generate encoded values 112. Continuing with this example, where the length-limited encoded produces encoded values 112 of a maximum of eight bits, the data structure 118 may include two hundred and fifty-six entries, one for each possible substring 202 of eight bits.

In some embodiments, the decoded value of each entry corresponds to a quantized value 114 to which the length-limited encoder was applied. In some embodiments, the quantized value 114 for the entry of a particular substring 202 is the quantized value 114 whose corresponding encoded value 112 is a prefix of the particular substring 202. For example, referring back to the example data structure 118 of FIG. 2B, the substrings 202 of “000,” “001,” “010,” and “001” each include a prefix of “0.” This prefix “0” matches the encoded value 112 for the quantized value 114 “0.1” as shown in the table 200 of FIG. 2A. Accordingly, each of these entries includes a quantized value 114 of “0.1.” In some embodiments, the prefix length 204 indicates a number of bits used by the matching prefix (e.g., the matching encoded value 112). Continuing with the example above, the substrings 202 of “000,” “001,” “010,” and “001” each include a prefix of “0,” which has a prefix length 204 of one.

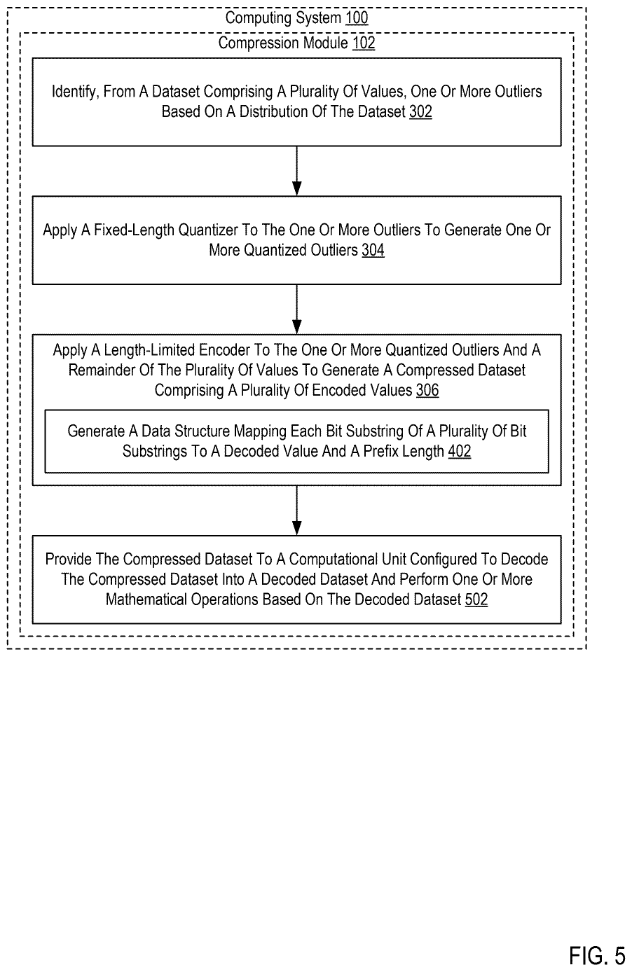

For further explanation, FIG. 5 sets forth a flowchart of another example method of variable bit length compression of matrices in accordance with some embodiments of the present disclosure. The method of FIG. 5 is similar to FIG. 4, differing in that the method of FIG. 5 also includes providing 502 the compressed dataset to a computational unit 108 configured to decode the compressed dataset into a decoded dataset and perform one or more mathematical operations based on the decoded dataset. For example, where the dataset is a matrix 104, providing 502 the compressed dataset to the computational unit 108 includes providing a compressed matrix 110 to the computational unit 108. In this example, the computational unit 108 is configured to decode the compressed matrix 110 into a decoded matrix 120 and perform one or more matrix operations using the decoded matrix 120 as an operand or parameter. As is set forth above, in some embodiments, the compression module 102 generates 402 a data structure 118 that facilitates decoding the dataset. Accordingly, in some embodiments, providing 502 the compressed dataset to the computational unit 108 also includes providing the data structure 118 to the computational unit 108.

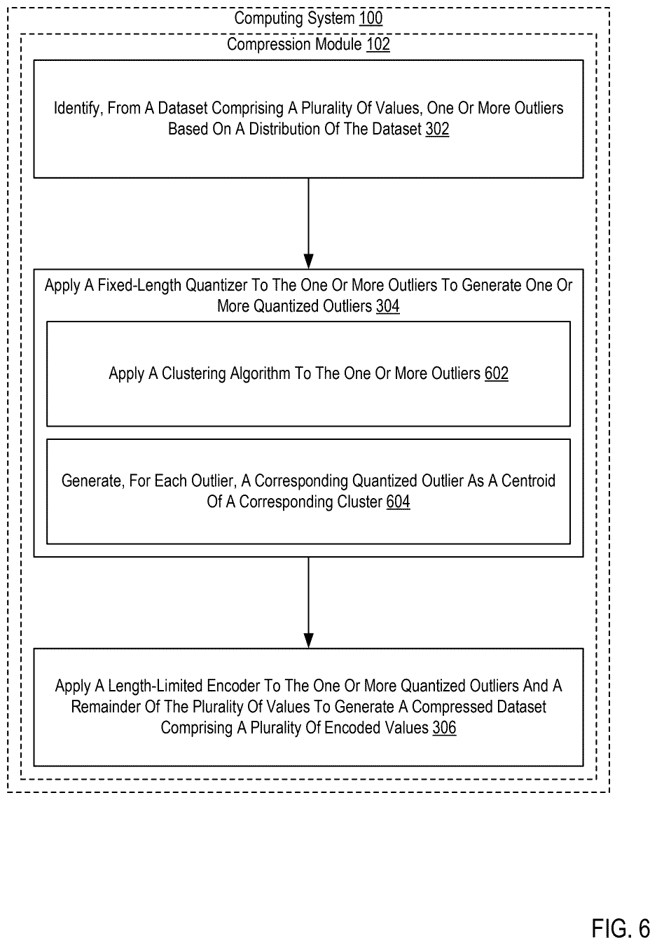

For further explanation, FIG. 6 sets forth a flowchart of another example method of variable bit length compression of matrices in accordance with some embodiments of the present disclosure. The method of FIG. 6 is similar to FIG. 3, differing in that applying 304 the fixed-length quantizer to the one or more outliers 116 to generate one or more quantized outliers 116 includes applying 602 a clustering algorithm to the one or more outliers 116. A clustering algorithm groups similar datapoints together into clusters. Accordingly, applying 602 the clustering algorithm to the one or more outliers 116 serves to map each outlier 116 to a cluster of one or more clusters.

Applying 602 the clustering algorithm may include applying any clustering algorithm as would be understood by one skilled in the art. For example, in some embodiments, applying 602 the clustering algorithm may include applying a k-means clustering algorithm to the one or more outliers 116, thereby mapping each outlier 116 to one of k clusters. In some embodiments, k (e.g., the number of clusters) may also include a tunable or configurable hyperparameter defined based on various design or engineering considerations. In some embodiments, another clustering algorithm may be applied 602 to the one or more outliers 116 so as to quantize the one or more outliers 116.

FIG. 6 further differs from FIG. 3 in that applying 304 the fixed-length quantizer to the one or more outliers 116 to generate one or more quantized outliers 116 also includes generating 604, for each outlier 116, a corresponding quantized outlier 116 as a centroid of a corresponding cluster (e.g., the cluster to which the outlier 116 is mapped). Thus, each outlier 116 is quantized by first mapping each outlier 116. The quantized value 114 for each outlier 116 is the centroid of the cluster to which it is mapped. Thus, one or more outliers 116 mapped to the same cluster will be quantized to the same centroid.

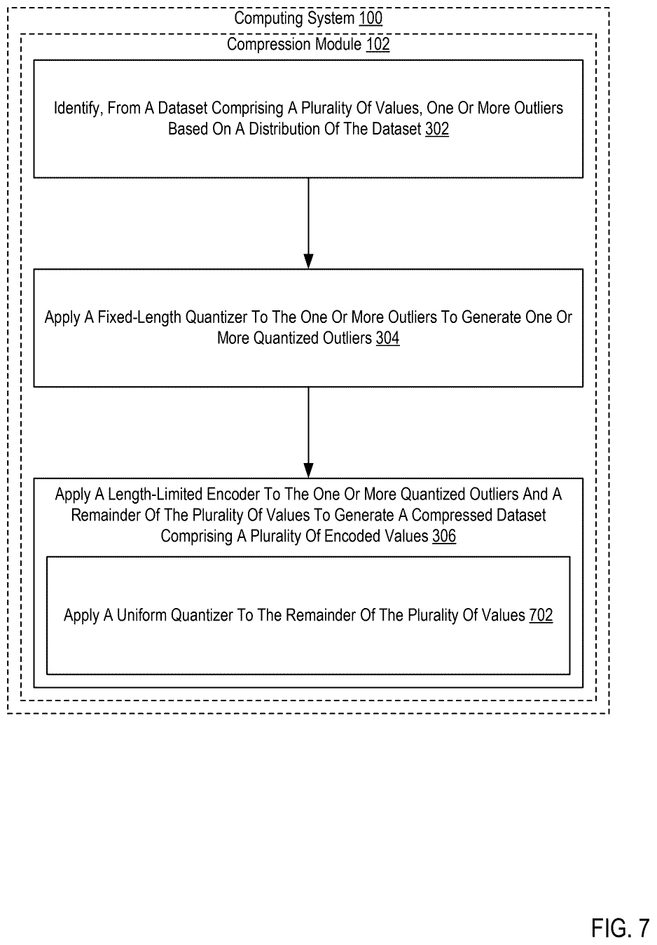

FIG. 7 sets forth a flowchart of another example method of variable bit length compression of matrices in accordance with some embodiments of the present disclosure. The method of FIG. 7 is similar to FIG. 3, differing in that applying 306 a length-limited encoder to the one or more quantized outliers 116 and a remainder of the plurality of values 106 other than the one or more outliers 116 to generate a compressed dataset comprising a plurality of encoded values 112 also includes applying 702 a uniform quantizer to the remainder of the plurality of values 106.

As is set forth above, in some embodiments, the one or more outliers 116 are quantized before encoding using a fixed-length quantizer. In some embodiments, the remainder of the values 106 (e.g., the non-outlier values 106) are also quantized before encoding. Accordingly, in some embodiments, a uniform quantizer is applied 702 to these remaining values 106. A uniform quantizer is a quantizing algorithm that maps each value 106 to one of a uniform distribution of possible quantized values 114. The distribution of possible quantized values 114 is uniform in that each quantized value 114 is equidistant to each adjacent quantized value 114 in the distribution. In other words, in some embodiments, each quantized value 114 may correspond to a multiple or interval of some fixed size. For example, in some embodiments, a set of possible quantized values 114 is generated for each interval of a fixed size h. In some embodiments, h is a configurable hyperparameter. Accordingly, each value 106 is quantized by rounding each value 106 to the closest multiple of the size h.

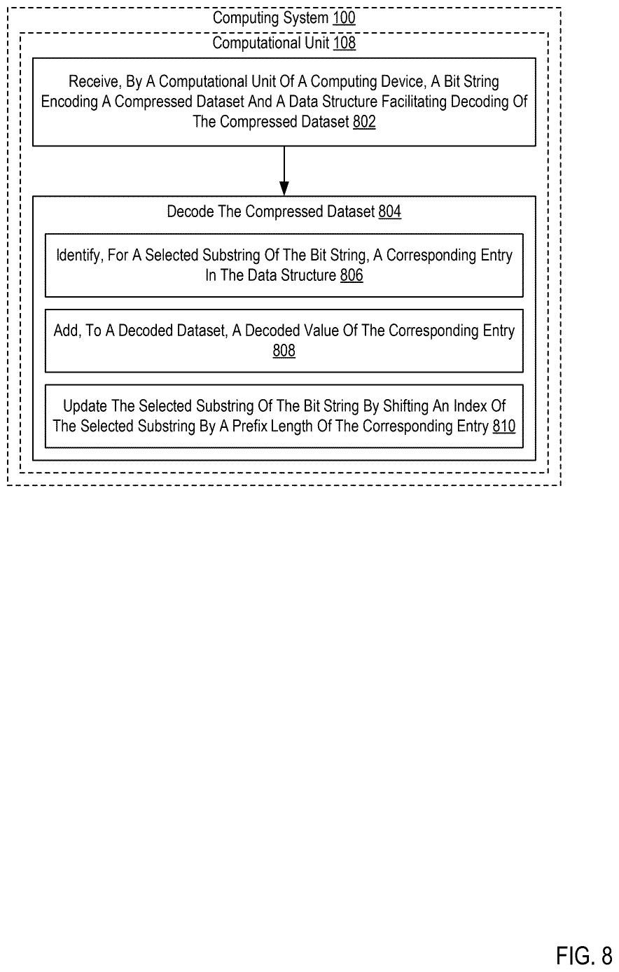

For further explanation, FIG. 8 sets forth a flowchart of another example method of variable bit length compression of matrices in accordance with some embodiments of the present disclosure. The method of FIG. 8 may be performed, for example, by a computational unit 108 of a computing system 100. Such a computational unit 108 may include a GPU, an AI accelerator, another type of hardware accelerator, or another hardware component as can be appreciated. The method of FIG. 8 includes receiving 802, by a computational unit 108 of a computing system 100, a bit string encoding a compressed dataset and a data structure 118 facilitating decoding of the compressed dataset. The compressed dataset may include a compressed matrix 110 or another set of encoded values 112 as can be appreciated. The bit string encoding the compressed dataset may include a concatenation or other arrangement of individual bit strings encoding each encoded value 112. In some embodiments, the computational unit 108 receives the bit string and the data structure 118 over a memory bus or other interface coupling the computational unit 108 to the computing system 100.

The method of FIG. 8 also includes decoding 804 the compressed dataset. Particularly, the computational unit 108 decodes 804 the compressed dataset using the received 802 data structure 118. In some embodiments, decoding 804 the compressed dataset includes repeatedly selecting fixed-length substrings 202 from the bit string and identifying a decoded value 114 from the prefix of the selected substring. Accordingly, in some embodiments, decoding 804 the compressed dataset includes identifying 806, for a selected substring 202 of the bit string, a corresponding entry in the data structure. In some embodiments, for a first iteration of the decoding 804 process, the computational unit 108 selects, as the selected substring 202, a leading substring 202 of the bit string. In some embodiments, each selected substring 202 is of a fixed length equal to the maximum number of bits used by the length-limited encoder. In other words, this selected substring 202 will have the same number of bits as the substrings 202 in the entries of the data structure 118. The identified entry of the data structure 118 is the entry whose substring 202 matches the selected substring 202.

In some embodiments, decoding 804 the compressed dataset also includes adding 808, to a decoded dataset (e.g., to a decoded matrix 120), a decoded value of the corresponding entry. For example, where the decoded values mapped by the data structure 118 include quantized values 114, the quantized value 114 is added to the decoded dataset. Decoding 804 the compressed dataset also includes updating 810 the selected substring 202 of the bit string by shifting an index of the selected substring 202 by a prefix length 204 of the corresponding entry. In some embodiments, this may include incrementing a pointer or identifier for the first bit of the selected substring 202 by this number of bits. In some embodiments, this may include performing a bit shift operation (e.g., a shift left) on the bit string encoding the compressed matrix 110 by this number of bits.

Having updated 810 the selected substring 202, an entry for the updated 810 selected substring 202 may be identified 806 and its decoded value added 808 to the decoded dataset as described above. Thus, the process of identifying 806, for a selected substring 202, a corresponding entry, adding 808 the decoded value to the decoded dataset, and updating 810 the selected substring 202 until the end of the bit string (e.g., until index of the selected substring 202 is greater than the last index of the bit string). This indicates that all bits of the bit string have been decoded, thereby indicating that the compressed dataset has been fully decoded 804. Readers will appreciate that, in some embodiments, the last one or more selected substrings 202 may include fewer than the maximum number of bits, depending on the ordering and prefix lengths 204 of the encoded values 112. Accordingly, in some embodiments, a matching entry for a selected substring 202 having fewer than the maximum number of bits is identified from the data structure 118 is identified 806 where the selected substring 202 matches the prefix of the substring 202 of the entry.

As an example, assume a compressed matrix 110 generated using a length-limited encoder with a maximum length of three bits, resulting in a data structure 118 to decode the compressed matrix 110 matching the example data structure 118 of FIG. 2B. Further assume that this compressed matrix 110 is encoded as a bit string with leading bits “010111. . . ” The initial selected substring 202 of this bit string will include the leading three bits of the bit string (e.g., indexes zero through two). This initial substring 202 of “010” is mapped to a quantized value of 0.1, which is then added to the decoded matrix 120. The index of the selected substring 202 is shifted by a prefix length 204 of one so that bits at indices one through three are selected. This substring 202 of “101” is mapped to a quantized value of 0.3, which is then added to the decoded matrix 120. The index of this selected substring 202 is shifted by a prefix length 204 of two so that bits at indices three through five are used to select a substring of “111.” This process then repeats across all bits of the bit string as described above until the decoded matrix 120 has been fully generated.

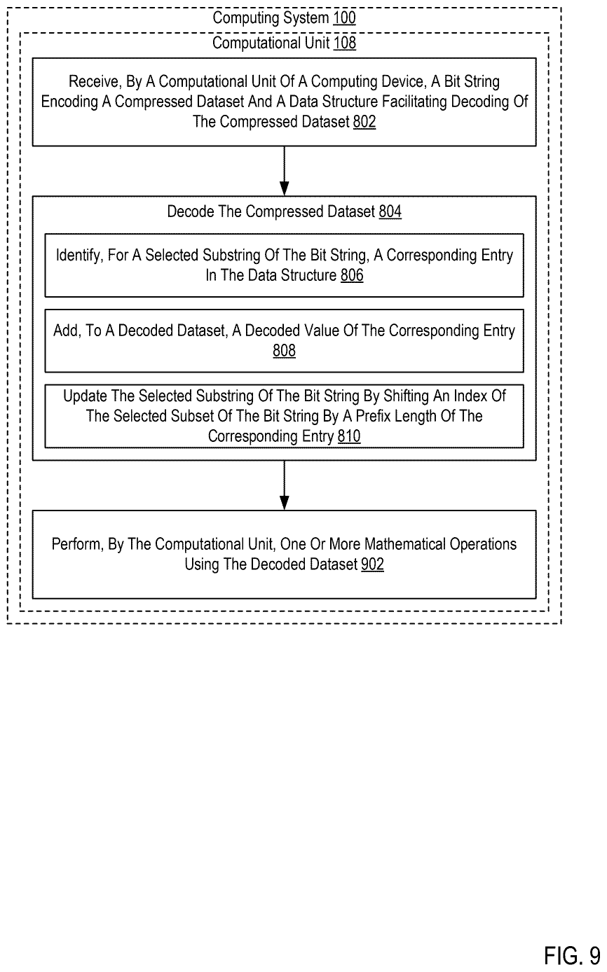

For further explanation, FIG. 9 sets forth a flowchart of another example method of variable bit length compression of matrices in accordance with some embodiments of the present disclosure. The method of FIG. 9 is similar to FIG. 8, differing in that the method of FIG. 9 also includes performing 902, by the computational unit 108, one or more mathematical operations using the decoded dataset. For example, where the decoded dataset includes a decoded matrix 120, performing 902 the one or more mathematical operations using the decoded dataset includes performing 902 one or more matrix operations using the decoded matrix 120 as a parameter or operand. Such matrix operations may include, for example, matrix multiplication, linear transformations, or other matrix operations as can be appreciated.

Readers will appreciate that some embodiments described above may leverage or be used in conjunction with one or more LLMs. An LLM is an AI model trained on extensive datasets, enabling it to generate coherent and contextually relevant textual responses. LLMs recognize patterns in language and can perform a variety of language-related tasks, including summarizing information, answering questions, translating between languages, and generating original content. Examples of LLMs may include, for example, ChatGPT, Llama, Granite, and the like. In other embodiments, however, one or more embodiments may leverage or be used in conjunction with other forms of generative AI. Other forms of generative AI beyond LLMs may include, for example, generative adversarial networks (GANs) used for generating realistic images or videos, diffusion models that may iteratively refine generated outputs in applications such as image synthesis, variational autoencoders (VAEs) that may learn to represent data distributions to create novel content, a small language model (SLM) trained on smaller-scale datasets with fewer parameters than LLMs which can make it more suitable for deployment in environments with limited computational resources or stringent latency constraints, or other generative AI model. These generative AI models can similarly benefit from matrix compression techniques to improve computational efficiency and performance.

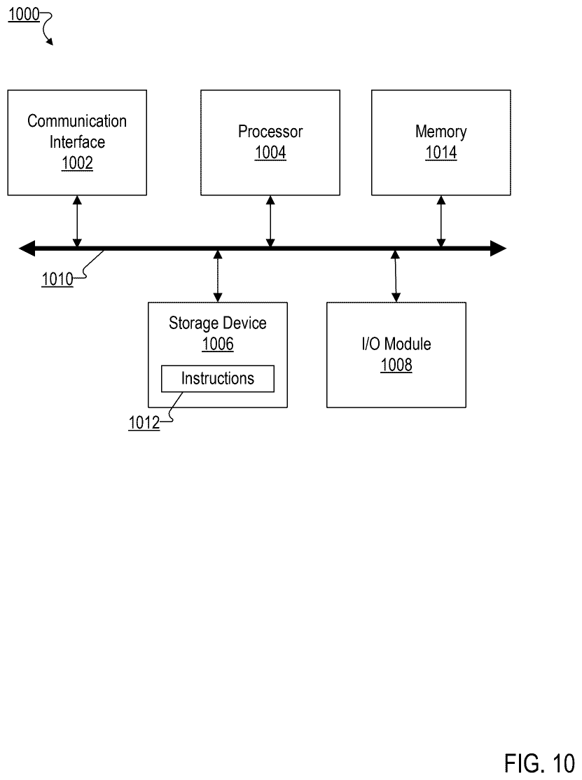

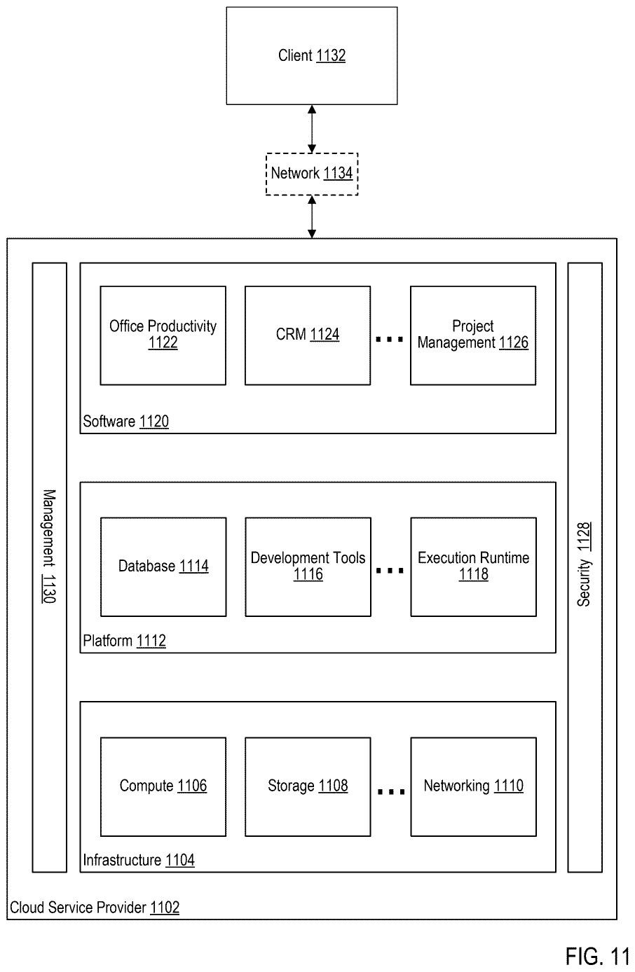

For further explanation, the sections included below provide some details regarding technologies that may be used to support variable bit length compression of matrices in accordance with some embodiments. For example, FIG. 10 sets forth an example of a computing device that may be used for some portion of securing an operating system in accordance with some embodiments. As an additional example of technologies that may be used to support variable bit length compression of matrices, FIG. 11 sets forth a block diagram of a cloud service provider 1102 service architecture in accordance with some embodiments of the present disclosure.

For further explanation, FIG. 10 illustrates an exemplary computing device 1000 that may be specifically configured to perform one or more of the processes described herein. As shown in FIG. 10, computing device 1000 may include a communication interface 1002, a processor 1004, a storage device 1006, an input/output (I/O) module 1008, and computer memory 1014 communicatively connected one to another via a communication infrastructure 1010. While an exemplary computing device 1000 is shown in FIG. 10, the components illustrated in FIG. 10 are not intended to be limiting. Additional or alternative components may be used in other embodiments. Components of computing device 1000 shown in FIG. 10 will now be described in additional detail.

Communication interface 1002 may be configured to communicate with one or more computing devices. Examples of communication interface 1002 include, without limitation, a wired network interface (such as a network interface card), a wireless network interface (such as a wireless network interface card), a modem, an audio/video connection, and any other suitable interface.

Processor 1004 generally represents any type or form of processing unit capable of processing data and/or interpreting, executing, and/or directing execution of one or more of the instructions, processes, and/or operations described herein. Processor 1004 may perform operations by executing computer-executable instructions 1012 (e.g., an application, software, code, and/or other executable data instance) stored in storage device 1006.

Storage device 1006 may include one or more data storage media, devices, or configurations and may employ any type, form, and combination of data storage media and/or device. For example, storage device 1006 may include, but is not limited to, any combination of non-volatile media and/or volatile media. Electronic data, including data described herein, may be temporarily and/or permanently stored in storage device 1006. For example, data representative of computer-executable instructions 1012 configured to direct processor 1004 to perform any of the operations described herein may be stored within storage device 1006. In some examples, data may be arranged in one or more databases residing within storage device 1006.

I/O module 1008 may include one or more I/O modules configured to receive user input and provide user output. I/O module 1008 may include any hardware, firmware, software, or combination thereof supportive of input and output capabilities. For example, I/O module 1008 may include hardware and/or software for capturing user input, including, but not limited to, a keyboard or keypad, a touchscreen component (e.g., touchscreen display), a receiver (e.g., an RF or infrared receiver), motion sensors, and/or one or more input buttons.

I/O module 1008 may include one or more devices for presenting output to a user, including, but not limited to, a graphics engine, a display (e.g., a display screen), one or more output drivers (e.g., display drivers), one or more audio speakers, and one or more audio drivers. In certain embodiments, I/O module 1008 is configured to provide graphical data to a display for presentation to a user. The graphical data may be representative of one or more graphical user interfaces and/or any other graphical content as may serve a particular implementation. In some examples, any of the systems, computing devices, and/or other components described herein may be implemented by computing device 1000.

For further explanation and as an additional example of a supporting technology for variable bit length compression of matrices, FIG. 11 sets forth a block diagram of a cloud service provider service architecture in accordance with some embodiments. The cloud service provider 1102 can deliver a variety of resources through a services-based consumption model where resources are consumed on-demand and as-a-service. Cloud service providers can provide services via cloud platforms such as, for example, Microsoft Azure™, Amazon Web Services (‘AWS’)™, Google Cloud Platform (‘GCP’)™, and others. In FIG. 11, the cloud service provider 1102 is accessed from a client device 1134 via a network 1132.

FIG. 11 depicts an embodiment where software 1120 is delivered as a service. Software-as-a-service (‘SaaS’) is a model where software applications are delivered over the internet as-a-service. Rather than installing and maintaining software locally, users can access software via a web browser or other network connected interface, eliminating the need for complex software and hardware management on the client-side. In FIG. 11, as examples of software 1120 that can be delivered as-a-service, the illustrated embodiment includes office productivity 1122 software, customer relationship management (‘CRM’) 1124 software, and project management 1126 software. The office productivity 1122 software can include applications designed to facilitate common business and personal tasks, including word processing applications, applications for spreadsheet creation, presentation design applications, and many others. The CRM 1124 software can include applications for managing a business organization's relationships and interactions with customers and potential customers. The project management 1126 software can include applications designed to help teams plan, organize, and manage projects efficiently by facilitating collaboration and tracking the progress of projects. Readers will appreciate that in other embodiments, other types of software may be delivered using a SaaS model.

FIG. 11 depicts an embodiment where platforms 1112 can be delivered as a service. Plat-form-as-a-service (‘PaaS’) is a model that provides cloud customers with platform resources that they can use to develop, run, and manage applications without the complexity of such deploying and managing such infrastructure on their own. In FIG. 11, as examples of platform 1112 resources that can be delivered as-a-service, the illustrated embodiment includes database 1114 services, development tools 1116 services, and execution runtime 1118 services. The database 1114 services can be used to provide access to databases without management overhead for the user as the cloud service provider manages the provisioning, scaling, and maintenance of the databases. The development tools 1116 services can provide developers with tools to design, develop, test, and deploy applications without needing to manage the underlying infrastructure. The execution runtime 1118 services can provide environments where applications or other forms of computer program code can be executed, including services to scale the execution environment. Readers will appreciate that in other embodiments, other platform resources may be delivered using a PaaS model.

FIG. 11 depicts an embodiment where infrastructure 1104 can be delivered as a service.

Infrastructure-as-a-Service (‘IaaS’) is a model that provides virtualized computing resources over the internet, such that infrastructure such as servers, storage, networks, and others may be leased on demand rather than purchasing and maintaining physical hardware. In FIG. 11, as examples of infrastructure 1104 resources that can be delivered as-a-service, the illustrated embodiment includes compute 1106 services, storage 1108 services, and networking 1110 services. The compute 1106 services can be used to provide on-demand access to computational resources such as VMs, containers, and serverless functions, where the cloud service provider manages the provisioning, scaling, and maintenance of such resources. The storage 1108 services can provide storage resources that can be used to store and access data, without the need for customers to purchase and manage on-premises physical storage resources. The networking 1110 services can provide the ability to create and manage virtualized networking resources such as, for example, virtual private networks (‘VPNs’), firewalls, load balancers, and more. Readers will appreciate that in other embodiments, other infrastructure resources may be delivered using a PaaS model.

The cloud service provider of FIG. 11 also provides management 1130 resources. The management 1130 resources can include, for example, tools and interfaces that enable customers to efficiently deploy, monitor, and manage, their cloud services. Such tools can include web-based management consoles, command-line interfaces (‘CLIs’), APIs, automation tools, and other tools.

The cloud service provider of FIG. 11 also provides security 1128 resources. The security 1128 resources can include, for example, tools and services to help customers protect their cloud environments and ensure compliance with security standards. These tools and services may provide specific aspects of security, including identity and access management, network security, threat detection, compliance management, and others.

Readers will appreciate that many of the components described above may be delivered as services from a cloud service provider. For example, the virtual machines, containers, and pods described above may all be delivered via a cloud service provider. In other embodiments, other forms of compute resources may be used in place of the virtual machines or other compute resource. For example, AWS EC2 instances or other form of cloud compute instances may be utilized in place of the virtual machines.

Advantages and features of the present disclosure can be further described by the following statements:
1. A method of variable bit length compression of matrices, comprising: identifying, from a dataset comprising a plurality of values, one or more outliers based on a distribution of the dataset; applying a fixed-length quantizer to the one or more outliers to generate one or more quantized outliers; and applying a length-limited encoder to the one or more quantized outliers and a remainder of the plurality of values to generate a compressed dataset comprising a plurality of encoded values.
2. The method of statement 1, wherein applying the length-limited encoder comprises generating a data structure mapping each bit substring of a plurality of bit substrings to a decoded value and a prefix length.
3. The method of statements 1 or 2, wherein the compressed dataset comprises a bit string and wherein the method further comprises: decoding the compressed dataset by repeatedly, until all bits of the bit string have been included in a selected substring of the bit string: identifying, for a selected substring of the bit string, a corresponding entry in the data structure; adding, to a decoded dataset, the decoded value of the corresponding entry; and updating the selected substring of the bit string by shifting an index of the selected substring by the prefix length of the corresponding entry.
4. The method of any combination of one or more of statements 1-3, wherein the selected substring of the bit string comprises a number of bits equal to a maximum length for the length-limited encoder.
5. The method of any combination of one or more of statements 1-4, further comprising providing the compressed dataset to a computational unit configured to: decode the compressed dataset into a decoded dataset; and perform one or more mathematical operations based on the decoded dataset.
6. The method of any combination of one or more of statements 1-5, wherein applying the fixed-length quantizer to the one or more outliers comprises: applying a clustering algorithm to the one or more outliers to map each outlier to a corresponding cluster of one or more clusters; and generating, for each outlier, a corresponding quantized outlier of the one or more quantized outliers as a centroid of the corresponding cluster.
7. The method of any combination of one or more of statements 1-6, wherein applying the length-limited encoder comprises applying a uniform quantization to the remainder of the plurality of values.
8. The method of any combination of one or more of statements 1-7, wherein the dataset comprises a matrix.
9. The method of any combination of one or more of statements 1-8, wherein the one or more outliers are identified based on an absolute value of each of the plurality of values.
10. An apparatus for variable bit length compression of matrices, comprising: a memory; and one or more processing devices, operatively coupled to the memory, the one or more processing devices configured to: identify, from a matrix comprising a plurality of values and facilitating an operation of a machine learning model, one or more outliers; apply a fixed-length quantizer to the one or more outliers to generate one or more quantized outliers; apply a variable-length encoder to the one or more quantized outliers and a remainder of the plurality of values to generate a compressed matrix comprising a plurality of encoded values; and provide the compressed matrix to a computational unit configured to perform the operation.
11. The apparatus of statement 10, wherein the operation comprises an inference operation or a training operation.
12. The apparatus of statements 11 or 12, wherein, to apply the variable-length encoder, the one or more processing devices are further configured to generate a data structure mapping each different encoded value of the plurality of encoded values to a decoded value and a prefix length.
13. The apparatus of any combination of one or more of statements 10-12, wherein the one or more processing devices are further configured to provide the data structure to the computational unit.
14. The apparatus of any combination of one or more of statements 10-13, wherein the plurality of values comprises a plurality of weights of the machine learning model.
15. The apparatus of any combination of one or more of statements 10-14, wherein the variable-length encoder comprises a length limited-Huffman encoder.
16. The apparatus of any combination of one or more of statements 10-15, wherein the computational unit comprises a graphics processing unit (GPU) or an artificial intelligence (AI) accelerator.
17. A method of variable bit length compression of matrices, comprising: receiving, by a computational unit of a computing device, a bit string encoding a compressed dataset and a data structure facilitating decoding of the compressed dataset; decoding, by the computational unit, the compressed dataset by repeatedly, until all bits of the bit string have been included in a selected substring of the bit string: identifying, for a selected substring of the bit string, a corresponding entry in the data structure; adding, to a decoded dataset, a decoded value of the corresponding entry; and updating the selected substring of the bit string by shifting an index of the selected substring by a prefix length of the corresponding entry.
18. The method of statement 17, further comprising performing, by the computational unit, one or more mathematical operations using the decoded dataset.
19. The method of statements 17 or 18, wherein the one or more mathematical operations comprise one or more matrix operations facilitating at least one of: a training operation of a machine learning model or an inference operation of a machine learning model.
20. The method of any combination of one or more of statements 10-17, wherein the compressed dataset comprises a plurality of encoded values each encoded using a length-limited encoder.

Although some embodiments are described largely in the context of a system, method, or in some other way, readers will recognize that embodiments of the present disclosure may also take the form of a computer program product disposed upon computer readable storage media for use with any suitable processing system. Such computer readable storage media may be any storage medium for machine-readable information, including magnetic media, optical media, solid-state media, or other suitable media. Examples of such media include magnetic disks in hard drives or diskettes, compact disks for optical drives, magnetic tape, and others as will occur to those of skill in the art. Persons skilled in the art will immediately recognize that any computer system having suitable programming means will be capable of executing the steps described herein as embodied in a computer program product. Persons skilled in the art will recognize also that, although some of the embodiments described in this specification are oriented to software installed and executing on computer hardware, nevertheless, alternative embodiments implemented as firmware or as hardware are well within the scope of the present disclosure.

Readers will appreciate that some embodiments are described in which computer program instructions are executed on computer hardware such as, for example, one or more computer processors. Readers will appreciate that in other embodiments, computer program instructions may be executed on virtualized computer hardware (e.g., one or more virtual machines), in one or more containers, in one or more cloud computing instances (e.g., one or more AWS EC2 instances), in one or more serverless compute instances offered such as those offered by a cloud services provider, in one or more event-driven compute services such as those offered by a cloud services provider, or in some other execution environment.

In some examples, a non-transitory computer-readable medium storing computer-readable instructions may be provided in accordance with the principles described herein. The instructions, when executed by a processor of a computing device, may direct the processor and/or computing device to perform one or more operations, including one or more of the operations described herein. Such instructions may be stored and/or transmitted using any of a variety of known computer-readable media.

A non-transitory computer-readable medium as referred to herein may include any non-transitory storage medium that participates in providing data (e.g., instructions) that may be read and/or executed by a computing device (e.g., by a processor of a computing device). For example, a non-transitory computer-readable medium may include, but is not limited to, any combination of non-volatile storage media and/or volatile storage media. Exemplary non-volatile storage media include, but are not limited to, read-only memory, flash memory, a solid-state drive, a magnetic storage device (e.g., a hard disk, a floppy disk, magnetic tape, etc.), ferroelectric random-access memory (“RAM”), and an optical disc (e.g., a compact disc, a digital video disc, a Blu-ray disc, etc.). Exemplary volatile storage media include, but are not limited to, RAM (e.g., dynamic RAM).

One or more embodiments may be described herein with the aid of method steps illustrating the performance of specified functions and relationships thereof. The boundaries and sequence of these functional building blocks and method steps have been arbitrarily defined herein for convenience of description. Alternate boundaries and sequences can be defined so long as the specified functions and relationships are appropriately performed. Any such alternate boundaries or sequences are thus within the scope and spirit of the claims. Further, the boundaries of these functional building blocks have been arbitrarily defined for convenience of description. Alternate boundaries could be defined as long as the certain significant functions are appropriately performed. Similarly, flow diagram blocks may also have been arbitrarily defined herein to illustrate certain significant functionality.

To the extent used, the flow diagram block boundaries and sequence could have been defined otherwise and still perform the certain significant functionality. Such alternate definitions of both functional building blocks and flow diagram blocks and sequences are thus within the scope and spirit of the claims. One of average skill in the art will also recognize that the functional building blocks, and other illustrative blocks, modules and components herein, can be implemented as illustrated or by discrete components, application specific integrated circuits, processors executing appropriate software and the like or any combination thereof.

While particular combinations of various functions and features of the one or more embodiments are expressly described herein, other combinations of these features and functions are likewise possible. The present disclosure is not limited by the particular examples disclosed herein and expressly incorporates these other combinations.

What is claimed is:

1. A method of variable bit length compression of matrices, comprising:
identifying, from a dataset comprising a plurality of values, one or more outliers based on a distribution of the dataset;
applying a fixed-length quantizer to the one or more outliers to generate one or more quantized outliers; and
applying a length-limited encoder to the one or more quantized outliers and a remainder of the plurality of values to generate a compressed dataset comprising a plurality of encoded values.

2. The method of claim 1, wherein applying the length-limited encoder comprises generating a data structure mapping each bit substring of a plurality of bit substrings to a decoded value and a prefix length.

3. The method of claim 2, wherein the compressed dataset comprises a bit string and wherein the method further comprises:
decoding the compressed dataset by repeatedly, until all bits of the bit string have been included in a selected substring of the bit string:
identifying, for the selected substring of the bit string, a corresponding entry in the data structure;
adding, to a decoded dataset, the decoded value of the corresponding entry; and
updating the selected substring of the bit string by shifting an index of the selected substring by the prefix length of the corresponding entry.

4. The method of claim 3, wherein the selected substring of the bit string comprises a number of bits equal to a maximum length for the length-limited encoder.

5. The method of claim 1, further comprising providing the compressed dataset to a computational unit configured to:
decode the compressed dataset into a decoded dataset; and
perform one or more mathematical operations based on the decoded dataset.

6. The method of claim 1, wherein applying the fixed-length quantizer to the one or more outliers comprises:
applying a clustering algorithm to the one or more outliers to map each outlier to a corresponding cluster of one or more clusters; and
generating, for each outlier, a corresponding quantized outlier of the one or more quantized outliers as a centroid of the corresponding cluster.

7. The method of claim 1, wherein applying the length-limited encoder comprises applying a uniform quantization to the remainder of the plurality of values.

8. The method of claim 1, wherein the dataset comprises a matrix.

9. The method of claim 1, wherein the one or more outliers are identified based on an absolute value of each of the plurality of values.

10. An apparatus for variable bit length compression of matrices, comprising:
a memory; and
one or more processing devices, operatively coupled to the memory, the one or more processing devices configured to:
identify, from a matrix comprising a plurality of values and facilitating an operation of a machine learning model, one or more outliers;
apply a fixed-length quantizer to the one or more outliers to generate one or more quantized outliers;
apply a variable-length encoder to the one or more quantized outliers and a remainder of the plurality of values to generate a compressed matrix comprising a plurality of encoded values; and
provide the compressed matrix to a computational unit configured to perform the operation.

11. The apparatus of claim 10, wherein the operation comprises an inference operation or a training operation.

12. The apparatus of claim 11, wherein, to apply the variable-length encoder, the one or more processing devices are further configured to generate a data structure mapping each different encoded value of the plurality of encoded values to a decoded value and a prefix length.

13. The apparatus of claim 12, wherein the one or more processing devices are further configured to provide the data structure to the computational unit.

14. The apparatus of claim 13, wherein the plurality of values comprises a plurality of weights of the machine learning model.

15. The apparatus of claim 10, wherein the variable-length encoder comprises a length limited-Huffman encoder.

16. The apparatus of claim 10, wherein the computational unit comprises a graphics processing unit (GPU) or an artificial intelligence (AI) accelerator.

17. A method of variable bit length compression of matrices, comprising:
receiving, by a computational unit of a computing device, a bit string encoding a compressed dataset and a data structure facilitating decoding of the compressed dataset; and decoding, by the computational unit, the compressed dataset by repeatedly, until all bits of the bit string have been included in a selected substring of the bit string:
identifying, for a selected substring of the bit string, a corresponding entry in the data structure;
adding, to a decoded dataset, a decoded value of the corresponding entry; and
updating the selected substring of the bit string by shifting an index of the selected substring by a prefix length of the corresponding entry.

18. The method of claim 17, further comprising performing, by the computational unit, one or more mathematical operations using the decoded dataset.

19. The method of claim 18, wherein the one or more mathematical operations comprise one or more matrix operations facilitating at least one of: a training operation of a machine learning model or an inference operation of a machine learning model.

20. The method of claim 17, wherein the compressed dataset comprises a plurality of encoded values each encoded using a length-limited encoder.
